(19) United States
(12) Patent Application Publication
(10) Pub. No.: US 2007/0170449 A1
(43) Pub. Date: Jul. 26, 2007

(54) Color sensor integrated light emitting diode for LED backlight

(76) Inventor: Munisamy Anandan, Del Valle, TX (US)

Correspondence Address: Dr. M. Anandan, 13009 Thome Valley Dr., Del Valle, TX, 78617, US

(21) Appl. No.: 11/656,685

(22) Filed: Jan. 22, 2007

Related U.S. Application Data
(60) Provisional application No. 60/761,468, filed on Jan. 24, 2006.

(51) Int. Cl. H01L 29/22; H01L 33/00

(52) U.S. Cl. 257/98

(57) ABSTRACT

A color sensor integrated light emitting diode (LED) is packaged with LED and color sensor mounted side by side inside LED package comprising a heat sink for mounting LED and the color sensor, both the color sensor and LED being buried by a high refractive index polymer followed by a diffuser layer and light extraction layer, all of which are transparent. Posts electrically linked to LED and color sensor inside the package are provided for external connection to LED and color sensor. Plurality of color sensors and LEDs can be packaged inside a single package with proper orientation of desired color LEDs to receive desired color by color sensors. Color change at the very source of light emission can be controlled with color sensor integrated LED package more effectively than conventional methods. Plurality of these packages can be employed for LED backlight for LCD, consumer lighting, decorative lighting and signage displays.

### CROSS REFERENCE TO RELATED APPLICATION

Benefit of Provisional application No. 60/761,468 filed Jan. 24, 2006

### Attorney file/docket#: MANAND1006.

U.S. Pat. No. 7,009,343—Lim et.al, Mar. 7, 2006
U.S. Pat. No. 6,507,159—Muthu, Jan. 14, 2003

### US patent application #2003023099 A1—Muthu et.al, Dec. 18, 2003

U.S. Pat. No. 6,411,046—Muthu, Jun. 25, 2002

### OTHER PUBLICATIONS

1. Armand Perduijin et.al—“Light output feedback solution for RGB LED backlight application”, SID'03 Digest of Technical papers, pp. 1254-57, SID International symposium 2003
2. Ki-Chan Lee et.al —“LED backlight feedback color control system with integrated amorphous silicon color sensor on an LCD panel”, Journal of the Society for Information Display (JSID), 14, 161 (2006)
3. Munisamy Anandan—“Backlight for LCD/TV Monitors: LCD vs CCFL”, Society for Information Display, Seminar Lecture Notes, SID International Symposium, San Francisco, Calif., Jun. 5, 2006.
4. Munisamy Anandan—“LED backlight for LCD/TV Monitor: Issues that remain”, SID International Symposium, Digest of Tech papers, Vol. XXXVII, Book II, pp. 1509-1512, Jun. 7-9, 2006, San Francisco, Calif., Jun. 5, 2006.
5. Munisamy Anandan—“LED backlights for LCD”, Tutorial Notes, Third Americas Display Engineering and Applications Conference (ADEAC) October 2006, Atalanta, Ga.
6. Munisamy Anandan—“LED Backlight: Enhancement of picture quality on LCD screen”. Proceedings of The 9th. Asian Symposium on Information Display, pp. 130-134, October, 2006, New Delhi, India

### STATEMENT REGARDING FEDERALLY SPONSORED RESEARCH OR DEVELOPMENT

Not Applicable

### REFERENCE TO SEQUENCE LISTING, A TABLE, OR A COMPUTER PROGRAM LISTING COMPACT DISK APPENDIX

Not Applicable

### BACKGROUND OF THE INVENTION

1. Field of Invention

Semiconductor based Light Emitting Diode (LED) emitting visible light in three primary red, blue and green colors and employing the color LEDs and mixing the colors through a diffuser or light guide to produce flat white light source for backlighting a Liquid Crystal Display (LCD).

LEDs are point sources of light and can emit in visible red, blue and green colors. Because of the richness of colors emitted by LEDs, they are employed increasingly to backlight LCDs to obtain high purity color pictures on LCD-TV screen. For backlighting LCD, a flat light source is needed. To obtain a flat light source from a point source of light coming out of LEDs, LEDs are assembled either at the edges of light guide or inside a light box. The light guide, usually a polycarbonate sheet, mixes the colors of individual LEDs and yields a white sheet of light. For high brightness application, high brightness LEDs are assembled inside a light box and a thick diffuser sheet is placed over the LEDs. The colors are pre-mixed at the bottom of the light box and further mixed at the diffuser. The diffuser sheet serves as the flat source of light for LCD. The white light thus obtained passes through the LCD and color images are generated by the incoming video signal to LCD in combination with the color filters employed inside LCD.

The brightness of LED backlight depends on the current flowing through individual LEDs. For obtaining high brightness on LCD screen, the current through LEDs is increased. The current increase has the effect of increasing the p-n junction temperature of LEDs. Junction temperature increase beyond 60⁰ C results in (i) the shift in the dominant wavelength of LED (ii) the deterioration of life (iii) the decrease in light generation. These changes are different for red, blue and green LEDs. Not to allow the junction temperature to exceed this limit, traditionally, packaging techniques of LEDs employ efficient heat sinking. Even these techniques are found to be inadequate in the case of high brightness LEDs. These changes are to be minimized in all applications of LEDs whether it is consumer lighting or LCD backlighting. In LCD backlighting, changes in dominant wavelength of LEDs will lead to the decrease in color purity of images and decrease in light output leads to images of low brightness and decrease in life is not desired. Similar is the case for LEDs employed in giant display used both for indoor and outdoor application. Color changes will be distinctly seen as poor quality color images, decreased brightness decrease the image quality and decreased life of LEDs increases the maintenance problems. If the changes are left uncorrected a ‘run-away’ phenomenon may set in, leading the destruction of LEDs.

2. Description of Prior Art

Prior art dealt with the changes in dominant wavelength, brightness and life of LEDs by employing color sensors in a convenient location in the display system or inside the light box. These sensors sense the changes in the characteristics of LEDs and give a signal that can be compared with the original characteristics and automatic corrections in drive condition for LEDs can be applied to restore the original conditions.

For example in one prior art (U.S. Pat. No. 7,009,343) Lim et.al described LED backlight for LCD and the control of spectral colors of LED, when the LEDs change their characteristics, through a spectral feedback control system that employed drivers, controller and color sensors. The color sensor sensed the light output characteristics from the LEDs and gave a feedback signal to the controller which generated a corrected drive signal that is delivered to the drivers. In the system employed by Lim et.al, the color sensor was placed in proximity to LCD over a small area and the light coming through LCD was sensed. As the LEDs employed for LED backlight for large area (40″ diagonal and above) LCD like the one used for LCD-TV, contains hundreds of LEDs with substantial spread in characteristics typical of LED manufacturing, sampling a small area of white light (mixed LED colors) that came through LCD and sensing change in dominant wavelength of LEDs is not a true representation of the changes taking place in the characteristics of individual LEDs or even a small group of LEDs among large number of groups. In this scheme it is difficult to obtain high quality color images on LCD screen.

In another prior art (U.S. Pat. No. 6,507,159) Muthu described a feedback control system for LED white luminary employed for consumer lighting application. This art used photo diodes with filters to sense the light out put changes from LEDs and converted the changes in to tristimulus values and compared the reference values to arrive at nullifying the difference to restore the white light characteristics for LED luminary. In this system the photo diodes with filters were assembled to receive the mixed white light from many LEDs. For small number of LEDs the problems are minimal in terms of changes in white chromaticity. For LED backlight for large area LCD, like TV or desk top computer where hundreds of LEDs are used sampling of light over a small area is not a true representation of the changes occurring in individual LEDs or small groups of LEDs among many groups.

A research paper by Ki-Chan Lee et.al [(“LED backlight feedback color control system with integrated amorphous silicon color sensor on an LCD panel”, Journal of the Society for Information Display JSID, 14, 161-2006], colors sensors were integrated to LCD at one edge to sample out the light coming through LCD and sense the change in dominant wavelength and generate the correction signal through a controller and then the correction signal is applied to the drivers. Here again the area over which the sampling was done did not truly represent the changes taking place in most of the LEDs.

In all the foregoing inventions, the color sensors did not sense the changes occurring in the dominant wavelength, brightness and life of most of the individual LEDs, as a result of junction temperature, and only sensed by sampling a small area of the white light obtained through mixing colors of light emitted by LEDs. This is not a true representation of the changes in characteristics of most of LEDs employed. In a large area LED backlight for LCD or decorative LED lighting of buildings or giant screen LED display, the quantity of LEDs run in to thousands. In such situations the color changes occur in many LEDs and difficult to monitor the changes over a large area and apply appropriate correction signal to LED drivers.

### BRIEF SUMMARY OF THE INVENTION

According to the present invention, changes in characteristic occurring in each LED, due to junction temperature increase, can be accurately sensed and the correction signal can be generated through controller and the LED drive can be effectively modified to control the color, white chromaticity coordinate, brightness and preserve life of LEDs. The present invention integrates color sensor to each LED during packaging and orients the color sensors to receive light rays emanating from LED chip. The shift in dominant wavelength, which bears a direct relation to junction temperature of LED, is sensed at the very source where the change takes place and the color sensor gives a feedback signal to the controller for further correction and subsequent change in the drive condition to LEDs. The LEDs with integrated color sensors can be employed in any number in any application including LCD backlighting, consumer lighting, architecture lighting, signage displays and decorative lighting and thus effectively control the color shift arising due to various reasons, primarily change in junction temperature. The color sensor integrated package is further integrated with optical components to make the package suitable for LCD backlighting.

It is an object of this invention to provide color sensor integrated LED packages that sense the color change (dominant wavelength change) taking place at each LED and sends out feedback signal to the controller for correction.

A further object of this invention is to provide a backlight unit for backlighting LCDs by incorporating multiplicity of color sensor integrated LED packages assembled at the edge of light guide for edge-lit mode or inside a light box for direct-lit mode.

Yet another object of this invention is to provide color sensor integrated LED packages further integrated with optical components suitable for LCD backlighting.

Yet another object of this invention is to provide color sensor integrated LED packages for LED luminary for any lighting application to control the color of lighting.

### BRIEF DESCRIPTION OF DRAWINGS

FIG. 1 is a cross-section of LED backlight illumination of LCD.

FIG. 2 is an exploded view of LED light box according to prior art.

FIG. 3 is a cross sectional view of LED backlight box according to prior art.

FIG. 4 is a block diagram of LED color control feedback system.

FIG. 5 is a cross section of LED package according to prior art.

FIG. 6 is an isometric view of LED package with three LED chip according to prior art.

FIG. 7 is a cross sectional view of LED package integrated with color sensor according to the present invention.

FIG. 8 is another embodiment of cross sectional view of LED package integrated with color sensor.

FIG. 9 is a cross sectional view of convex mirror assembly over color sensor integrated LED package.

FIG. 10 is a schematic of color sensor feedback control.

FIG. 11a is an isometric view of color mixing through fiber bundle assembled to the color sensor integrated LED package according to the present invention.

FIG. 11b is an isometric view of another embodiment of fiber bundle assembled to the color sensor integrated LED package according to the present invention.

FIG. 12 is an exploded view of a backlight box incorporating color sensor integrated LED package of the present invention with assembly of fiber bundle over the LED package,

FIG. 13 is an exploded view of a backlight box incorporating color sensor integrated LED package of the present invention with assembly of LED package with convex mirror.

FIG. 14 is a plan view of LED edge-type backlight with color sensor integrated LEDs assembled at the edge of light guide.

### DETAILED DESCRIPTION OF DRAWINGS

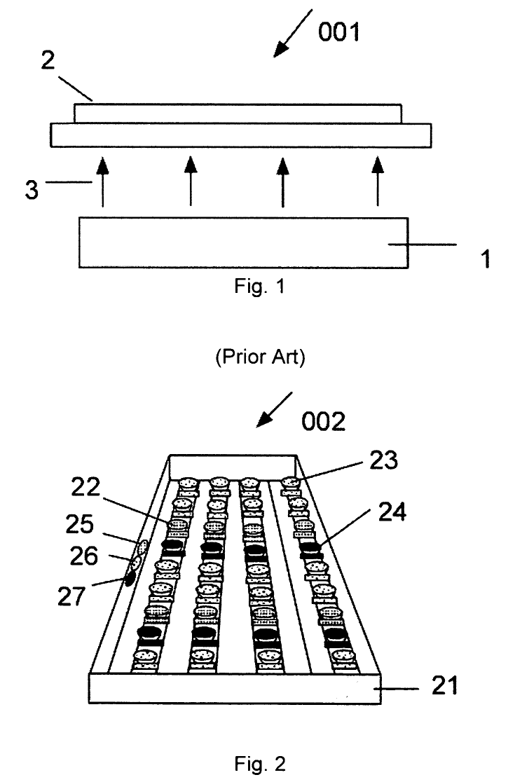

FIG. 1 is a cross-section of LCD backlighting using LED backlight illumination according to prior art. The backlight and LCD system 001 consists of LED backlight box 1 that sends uniform white light 3 to the back of LCD 2.

FIG. 2 is an exploded view of LED light box 002 according to prior art. Red LEDs 22, blue LEDs 23 and green LEDs 24 are assembled in rows and columns with a predetermined pitch inside a box 21 that has optical elements (not shown in FIG. 2) and the edge of the box 21 contains red color sensor 25, blue color sensor 26 and green color sensor 27. Above this light box will be assembled a diffuser sheet and other optical films not shown in FIG. 2. These LEDs are emitting light at the side and not upward. The reason being that the red, blue and green colors need to be mixed at the backlight box prior to illuminating LCD. The color sensors sense any change in color (relating to the change in dominant wavelength) of LEDs and send a feedback signal to the controller to correct the color change. In this prior art the color sensors are located at one edge of backlight box 002 to control the population of hundreds of LEDs assembled inside the box 21

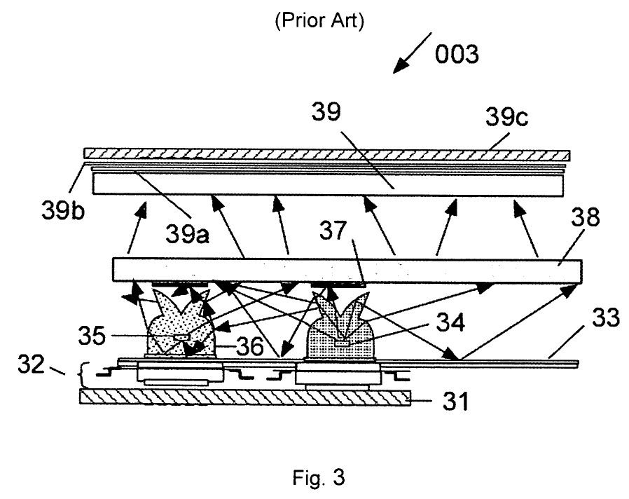

FIG. 3 is a cross sectional view of LED backlight box according to prior art. This cross sectional view 003 contains, in addition to LEDs, all the optical films (not shown in FIG. 2) that are assembled above the light box. Shown in FIG. 3 are just two LEDs, red 35 and blue 34, for illustration purpose only. In fact there will be hundreds of red, blue and green LEDs assembled inside the light box. The color mixing is shown by arrows between the PMMA plate 38 and white reflector 33. LEDs are assembled on Aluminum plate with fixture 32 which is fixed over PCB 31. The color light well mixed emerge as white light after passing through PMMA plate 38 and further thoroughly mixed after passing through a thick diffuser 39. A stop 37 is placed over the LEDs to prevent direct color ray entering PMMA plate without mixing. Brightness enhancement film 39a, usually two orthogonal prism sheets, is followed by double brightness enhancement film 39b that acts as polarization recycling. Finally the light falls on LCD 39c. As there are hundreds of LEDs inside the light box, just three color sensors at the edge of the box will not accurately control the color as there could be other groups of LEDs remote from the color sensor which could still run away from the current and change the wavelength. Location of color sensors at the edge of the backlight box is not a true master detector of change in color for a large population of LEDs.

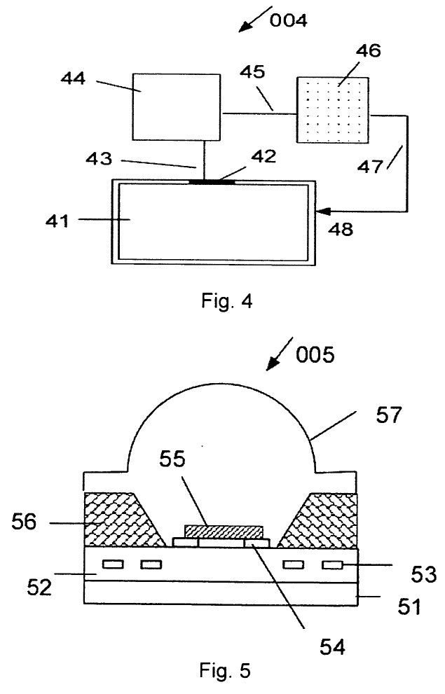

FIG. 4 is a block diagram of color control feedback system 004. The color sensors 42 assembled at one end of direct backlight box 41 gives out sensor signal 43 based on the color change and this signal goes to PIC controller 44. The PIC controller 44 compares the pulse width modulation (PWM) reference signal and modifies the PWM signal and send this modified signal 45 to the LED driver 46. The LED driver alters its drive signal 47 in accordance with modified PWM and drive the LEDs 48 to retain their color.

FIG. 5 is a cross section of LED package 005 according to prior art. LED chip 55 is mounted on wiring pad 54 that is contained on a PCB 52 with several contact pads 53 and PCB is attached to a metal substrate 51 for conducting heat away. A tapered epoxy 56 adjacent to the LED chip 55 contains a plastic lens 57 that focuses the light towards the viewer.

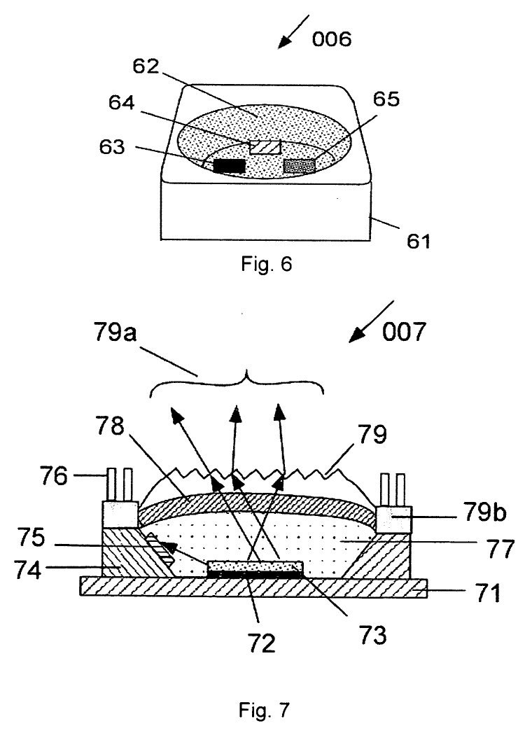

FIG. 6 is an isometric view of LED package 006 with three LED chip according to prior art. The package 006 consists of a ceramic housing 61 with a cavity 62 whose inside surface is reflecting. The cavity contains red LED chip 63, blue LED chip 64 and green LED chip 65 bonded in a triangle. The colored light emitted by the individual LEDs undergo pre-mixing through multiple reflections at the reflecting surfaces of the cavity. When viewed from top at a distance the LEDs together appear near white in color.

FIG. 7 is a cross sectional view of LED package 007 integrated with color sensor according to the present invention. LED chip 73 is mounted on heat sink 71 through a heat conductive epoxy 72. A reflective metal mount with a taper 74 contains color sensor 75 that faces the LED chip 73 laterally. Light rays from the edge and surface of LED chip, shown by arrow, are incident on color sensor. Two posts 76, embedded in epoxy block 79b, serve as electrical connection to color sensor and LED. For the sake of simplicity the connection from sensor and LED chip to posts is not shown in FIG. 7. High refractive index polymer (refractive index of 1.9-2.8) 77 is filled-in to extract light from LED chip. A diffuser layer 78 is followed by another polymer layer with light extraction feature 79. All the extracted rays 79a from the structure travel upwards. A tremendous advantage this structure offers is the sensing of color change (dominant wavelength change) of light rays emitted by LED at the very source where the change takes place and representative of every LED chip. If red LED chip is employed, the red color sensor, usually a photo diode with red filter on top, will sense the red color (dominant wavelength in red) and thus the sensor feedback signal from every package is available for feedback control. This advantage is not available in the LED packages of prior art. The LED package 007 shown in the present invention can be employed in any application starting from consumer lighting to signage displays to LCD backlighting for controlling and stabilizing the required color of light from LEDs.

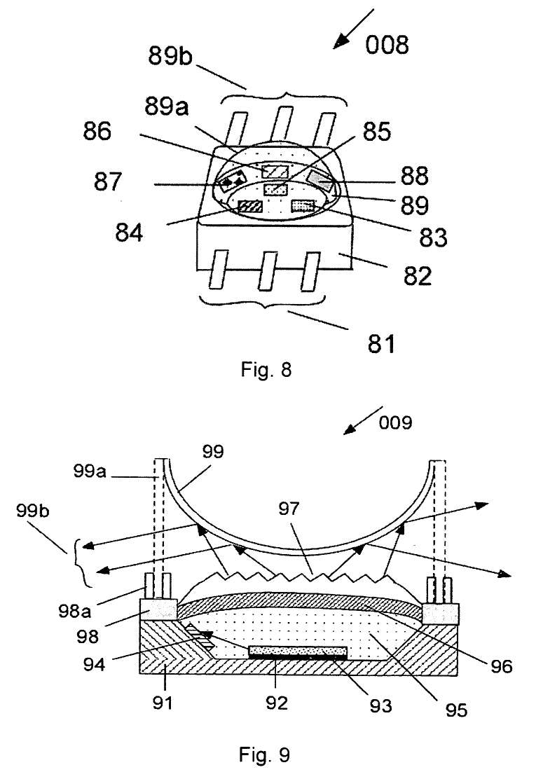

FIG. 8 is another embodiment of cross sectional view of LED package 008 integrated with color sensor. The package contains red LED chip 83, blue LED chip 84 and green LED chip 85 contained in housing 82. Color sensor for red 88, color sensor for blue 87 and color sensor for green 86 are located on the inside reflecting surface of the package. A lens 89a is sealed over the package to direct the RGB pre-mixed white light upwards. The package 008 is provided with external leads for electrically connecting to the LED chips and color sensors.

FIG. 9 is a cross sectional view of convex mirror assembly over color sensor integrated LED package 009. LED chip 93 is mounted on a metal substrate 91 through a conductive epoxy 92. Appropriate color sensor 94 that matches with the color of light emitted by LED chip is mounted at an angle facing the light rays, shown by arrow, emitted from LED 93. A polymer layer 95 of high refractive index (refractive index of 1.9-2.8) is filled burying the LED and color sensor followed by a diffuser layer 96 and further followed by a plastic layer with light extraction feature 97. Electrical connecting wires are embedded in the polymer 95 and are not shown for simplicity. The posts 98a embedded in epoxy block 98 serves as external connecting post for the color sensor and LED chip. A convex mirror 99, obtained through metallic coating of plastic surface, whose bottom surface is reflective, is supported by three lugs 99a, one lug is not shown for simplicity. The light 99b extracted from the package by the extraction features 97 is deflected side-wards for them to be incident on a reflecting surface, not shown in FIG. 9, of a backlight box for color mixing.

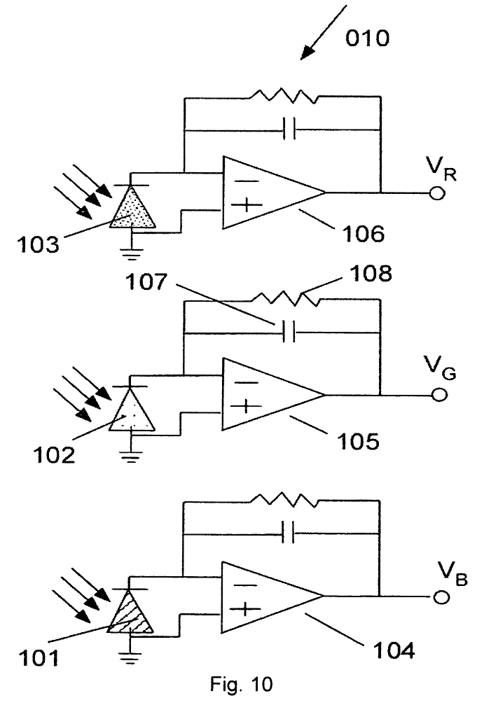

FIG. 10 is a schematic of color sensor feedback control 010. Color sensor 101 for blue, 102 for green and 103 for red are connected to a trans-impedance amplifiers 104, 105 and 106 respectively. Decoupling capacitor 107 and feedback resistor 108 are also shown for each color sensor. The light falling on color sensors produces current, for a particular color with color point x and y signifying purity of color related to the dominant wavelength, and this is converted in to voltage output by the trans-impedance amplifiers 104, 105 and 106. V_{R} represents the voltage output for red color, V_{B} represents voltage output for blue color and similarly V_{G} represents the voltage output for green color.

Designer can set desired initial conditions of all three colors by appropriately adjusting the pulse width modulation for each color LED and obtaining the voltage output from the trans-impedance amplifier. This voltage, representative of the desired initial color for each color LED is stored as reference voltage in a controller. Any change in color, as a result of change in dominant wavelength and intensity of LED, changes the current through color sensor thus resulting in a voltage output different from the reference voltage produced and stored in the controller. This change in voltage is compared with the reference voltage for the color in question by the controller and the controller generates a different pulse width modulated signal that is used to drive the LEDs to restore the initial set conditions. Thus a ‘run-away’ from color and brightness of LEDs is prevented.

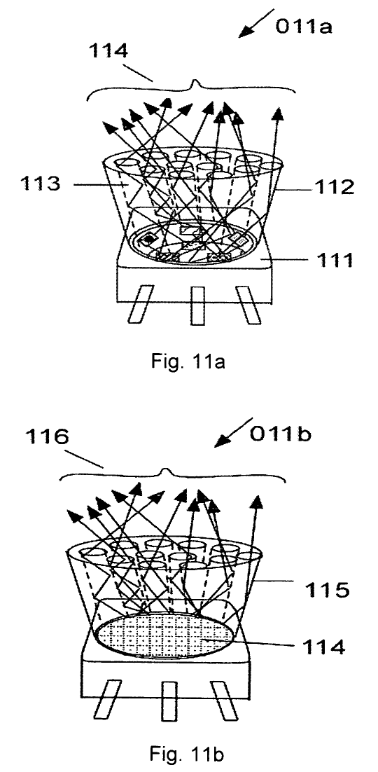

FIG. 11a is an isometric view of color mixing through fiber bundle assembled to the color sensor integrated LED package 011a according to the present invention. LED package with integrated color sensor package 111 is assembled with a fiber bundle 112 comprising multiplicity of fanned fibers 113. The pre-mixed colors from the package 111 that contains both LEDs and color sensors as shown in previous FIG. 8 are further thoroughly mixed in the fibers through multiple total internal reflections and the resulting white light 114 emerges upwards. This can be employed in LED backlight for LCD without the use of dense diffusers which cause light loss.

FIG. 11b is an isometric view of another embodiment 011b of fiber bundle assembled to the color sensor integrated LED package according to the present invention. The package is different from the one shown in FIG. 11a with filling of the cavity in FIG. 11a with transparent high refractive index polymer 114 and the fiber bundle 115 is embedded in the high refractive index polymer layer. This package can yield high light extraction compared to the package in FIG. 11a and the resulting light rays mixed thoroughly as they travel through the fibers emerge as white light 116.

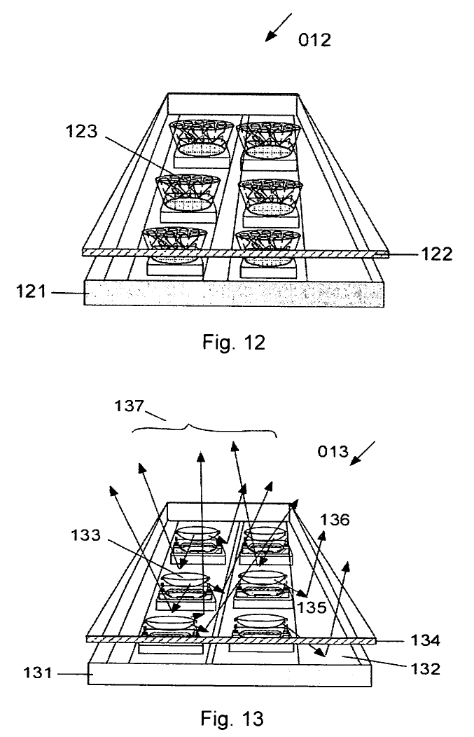

FIG. 12 is an exploded view of a backlight box 012 incorporating color sensor integrated LED package of the present invention with assembly of fiber bundle over the LED package. The package 123 shown in FIG. 11a or 11b can be assembled inside a light box 121 in several rows and columns and the resulting white light emerging from the package can be made to pass through a low density diffuser 122 and can be utilized to create R-G-B mixed white backlight for LCD. Use of low density diffuser minimizes light loss. The colors sensors contained inside the package are used to obtain the feedback signal for stabilizing the color of red, blue and green.

FIG. 13 is an exploded view of a backlight box 013 incorporating color sensor integrated LED package of the present invention with assembly of LED package with convex mirror. The box 131 contains plurality of packages shown in FIG. 9 wherein a convex mirror attached to the sensor integrated packages 133 are arranged in rows and column inside the box 131 and the deflected rays from the mirrors are incident on the bottom reflector of the box. After reflection at the reflector of the light box the rays go through a low density diffuser 134. For illustration purpose, one such ray 135 that comes after deflection from the convex mirror is incident at the reflector 132 of the light box and after reflection pass through the diffuser as ray 136. After the diffuser all the rays 137 emerge as white light for backlighting LCD. Backlight designs shown in FIGS. 12 and 13 can be used for high brightness LED backlight for LCDs employed in LCD TV.

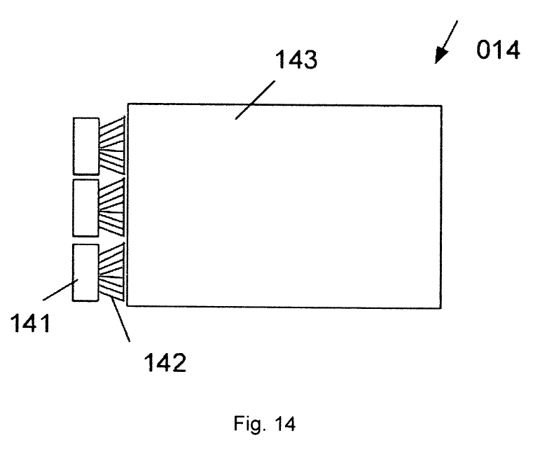

FIG. 14 is a plan view of LED edge-type backlight 014 with color sensor integrated LED packages assembled at the edge of light guide. Color sensor integrated LED packages shown in FIG. 8 or FIG. 11a or FIG. 11b can be assembled as edge light sources 141 at the edge of a light guide 143. If the package is assembled with fiber bundle 142 it has the advantage of better color mixing of light, prior to the entry in to the light guide 143. This type of backlight can be used in desk top and lap top computer LCDs.

It will be understood that one skilled in the art could modify the above basic design, geometries, sequence of assemblies. Various modification and variations can be made in the construction, configuration and/or operation of the present invention without departing from the scope or spirit of the invention. By way of examples, (i) not all LED packages with integrated color sensors need to be assembled inside the light box, instead a few of the packages can be distributed in certain configuration and the remaining packages can be normal packages without integrated color sensors (ii) three-in-one RGB LED package with color sensors integrated, as illustrated in the Figures above, can be in-line RGB LED with in-line color sensors (iii) Color sensor integrated LED packages can be constructed with different geometries with different materials (iv) the illustration for edge-type backlight employs color sensor integrated LED packages at only one edge of the light guide, but it can also be at more than one edge. Thus it is intended that the present invention covers the modifications and variations of the invention provided they come within the scope of the appended claims and their equivalents.

We claim:

1. A color sensor integrated light emitting diode package for LED backlight for LCD comprising:
an LED and a color sensor placed adjacent to each other enabling the color sensor to receive the light rays emitted by LED;
said color sensor and LED mounted on a heat sinking structure and buried by a high refractive index polymer;
said high refractive index polymer coated with a diffuser film;
said diffuser film coated with light extracting structure;
means for connecting LED and color sensor integrally packaged;
said integral package applied with suitable voltage for LED to emit desired color light and color sensor to receive the desired color light and produce current characteristic of color light.

2. A color sensor integrated LED package as claimed in claim 1 wherein the package contains plurality of LEDs emitting red, blue and green light and plurality of color sensors disposed in appropriate orientation to enable color sensors receive the desired color light from LEDs.

3. A color sensor integrated LED package as claimed in claim 2 wherein the package contains reflective cavity that houses LEDs and color sensors to pre-mix the colors to obtain white light.

4. A color sensor integrated LED package as claimed in claim 3 wherein the package is assembled with optical fiber bundle to the cavity for complete color mixing and guiding the light upwards.

5. A color sensor integrated LED package as claimed in claim 1 wherein plurality of the said package can be used for LCD backlighting.

6. A color sensor integrated LED package as claimed in claim 2 wherein plurality of said package can be used for LCD backlighting.

7. A color sensor integrated LED package as claimed in claim 3 wherein plurality of said package can be used for LCD backlighting.

8. A color sensor integrated LED package as claimed in claim 4 wherein plurality of said package can be used for LCD backlighting.

9. A color sensor integrated LED package as claimed in claim 1 wherein plurality of said package can be used for consumer lighting application.

10. A color sensor integrated LED package as claimed in claim 2 wherein plurality of said package can be used for consumer lighting application.

11. A color sensor integrated LED package as claimed in claim 3 wherein plurality of said package can be used for consumer lighting application.

12. A color sensor integrated LED package as claimed in claim 4 wherein plurality of said package can be used for consumer lighting application.

13. A color sensor integrated LED package as claimed in claim 1 wherein plurality of said package can be used for decorative lighting application.

14. A color sensor integrated LED package as claimed in claim 2 wherein plurality of said package can be used for decorative lighting application.

15. A color sensor integrated LED package as claimed in claim 3 wherein plurality of said package can be used for decorative lighting application.

16. A color sensor integrated LED package as claimed in claim 4 wherein plurality of said package can be used for decorative lighting application

17. A color sensor integrated LED package as claimed in claim 1 wherein plurality of said package can be used for signage display application.

18. A color sensor integrated LED package as claimed in claim 2 wherein plurality of said package can be used for signage display application.

19. A color sensor integrated LED package as claimed in claim 3 wherein plurality of said package can be used for signage display application.

20. A color sensor integrated LED package as claimed in claim 4 wherein plurality of said package can be used for signage display application.
